(19) United States
(12) Patent Application Publication
(10) Pub. No.: US 2018/0204747 A1
(43) Pub. Date: Jul. 19, 2018

(54) SUBSTRATE SUPPORT ASSEMBLY HAVING SURFACE FEATURES TO IMPROVE THERMAL PERFORMANCE

(71) Applicant: Applied Materials, Inc., Santa Clara, CA (US)

(72) Inventor: Vladimir Knyazik, Santa Clara, CA (US)

(21) Appl. No.: 15/408,234

(22) Filed: Jan. 17, 2017

(51) Int. Cl. H01L 21/67; C04B 41/53; C04B 41/91; C04B 41/45; C04B 41/81; C04B 37/02; C09K 5/14; H01L 21/683

(52) U.S. Cl. CPC H01L 21/67103; C04B 41/5346; C04B 41/91; C04B 41/4592; C04B 2237/32; C04B 37/02; C09K 5/14; H01L 21/6833; C04B 2237/40; C04B 41/81

(57) ABSTRACT

A substrate support assembly including a ceramic body includes an upper surface. The upper surface includes a sealing ring at a periphery of the ceramic body, a plurality of mesas and a plurality of recessed features, wherein the plurality of recessed features are formed between the plurality of mesas. The ceramic body further includes one or more through holes to receive a thermally conductive gas, wherein molecules of the thermally conductive gas are to collide with the walls of the plurality of recessed features to increase an effective thermal accommodation coefficient (TAC) associated with the upper surface and increase an effective thermal conductivity of the thermally conductive gas as a result of the increase in the effective TAC associated with the upper surface.

### TECHNICAL FIELD

Embodiments of the present invention relate, in general, to a substrate support assembly such as an electrostatic chuck that has surface features to improve thermal performance.

### BACKGROUND

In the semiconductor industry, devices are fabricated by a number of manufacturing processes producing structures of an ever-decreasing size. Some manufacturing processes such as plasma etch expose a substrate to a plasma to etch the substrate. The manufacturing processes may require increased power levels during the plasma etch, resulting in increased heat flux on the substrate. The increase in heat flux may make it difficult to control the temperature of the substrate.

### SUMMARY

In one embodiment, a substrate support assembly including a ceramic body includes an upper surface. The upper surface includes a sealing ring at a periphery of the ceramic body, a plurality of mesas and a plurality of recessed features, wherein the plurality of recessed features are formed between the plurality of mesas. The ceramic body further includes one or more through holes to receive a thermally conductive gas, wherein the molecules of thermally conductive gas is to collide with the walls of the plurality of recessed features to increase an effective thermal accommodation coefficient (TAC) associated with the upper surface and increase an effective thermal conductivity of the thermally conductive gas as a result of the increase in the effective TAC associated with the upper surface.

In one embodiment, a method includes forming a plurality of mesas on an upper surface of a ceramic body for a substrate support assembly, forming a sealing ring on the upper surface of the ceramic body and forming at least one of a plurality of recessed features between the plurality of mesas on the upper surface of the ceramic body or a plurality of protrusions between the plurality of mesas on the upper surface of the ceramic body. The method further includes forming one or more through holes in the ceramic body, wherein the one or more through holes are to receive a thermally conductive gas. The molecules of thermally conductive gas is to collide with walls of at least one of the plurality of recessed features or the plurality of protrusions to increase an effective TAC of the upper surface and increase an effective thermal conductivity of the thermally conductive gas as a result of the increase in the effective TAC of the upper surface.

In one embodiment, a substrate support assembly includes a ceramic body including an upper surface. The upper surface includes a sealing ring at a periphery of the ceramic body, a plurality of mesas and a plurality of protrusions, wherein the plurality of protrusions are formed between the plurality of mesas. The ceramic body further includes one or more through holes to receive a thermally conductive gas, wherein the molecules of thermally conductive gas is to collide with walls of the plurality of recessed features to increase an effective TAC associated with the upper surface and increase an effective thermal conductivity of the thermally conductive gas as a result of the increase in the effective TAC associated with the upper surface.

### BRIEF DESCRIPTION OF THE DRAWINGS

Embodiments of the present invention are illustrated by way of example, and not by way of limitation, in the figures of the accompanying drawings in which like references indicate similar elements. It should be noted that different references to “an” or “one” embodiment in this disclosure are not necessarily to the same embodiment, and such references mean at least one.

FIG. 1 depicts a sectional view of one embodiment of a processing chamber.

FIG. 2 depicts an exploded view of one embodiment of a substrate support assembly surface.

FIG. 3A depicts a side view of one embodiment of a substrate support assembly.

FIG. 3B depicts a side view of one embodiment of a substrate support assembly.

FIG. 3C depicts a side view of one embodiment of a substrate support assembly.

FIG. 4A illustrates a cross sectional view of a recessed feature in the ceramic body, according to embodiments.

FIG. 4B is a graph illustrating the relationship of the aspect ratio of the recessed features to the effective TAC of the thermally conductive gas in the recessed feature.

FIG. 5A is an isometric view of the upper surface of the ceramic body of one embodiment of a substrate support assembly, including a pattern of recessed features.

FIG. 5B is a graph illustrating the relationship of the aspect ratio of the recessed features of the ceramic body to the percent increase of effective thermal conductivity of the thermally conductive gas.

FIG. 6 illustrates a cross sectional view of protrusions in the ceramic body of a substrate support assembly, according to embodiments.

FIG. 7 illustrates one embodiment of a process for forming recessed features in the ceramic body of a substrate support surface.

FIG. 8 illustrates another embodiment of a process for forming protrusions on a ceramic body of a substrate support surface.

### DETAILED DESCRIPTION OF EMBODIMENTS

Embodiments of the present invention provide a substrate support assembly that includes a ceramic body (e.g., an electrostatic chuck) that interfaces with and supports a substrate such as a wafer. The ceramic body has a series or pattern of recessed features or protrusions formed on the upper surface of the ceramic body. A thermally conductive gas may be pumped into a volume between the upper surface of the ceramic body and a supported substrate to facilitate the transferring of heat between the substrate and the ceramic body. Molecules of the thermally conductive gas may collide with the upper surface of the ceramic body, transferring energy between the ceramic body and the gas. The molecules of thermally conductive gas may then collide with the supported substrate and exchange the thermal energy with the substrate. A thermal accommodation coefficient (TAC) may specify the energy transferred between the upper surface of the ceramic body and the molecules of the thermally conductive gas. Forming a series of recessed features or protrusions on the upper surface of the ceramic body may result in an increased number of collisions between the molecules of the thermally conductive gas and the upper surface of the ceramic body compared to a planar upper surface due to possible collisions of molecules of the thermally conductive gas with the walls of the recessed features or protrusions. The increased number of collisions may result in an increase in the effective TAC of the thermally conductive gas and a corresponding increase in the effective thermal conductivity of the thermally conductive gas. The improved effective TAC and effective thermal conductivity provided by the recessed features or protrusions may improve the heat transfer between the substrate and the ceramic body, allowing for improved temperature control of the substrate.

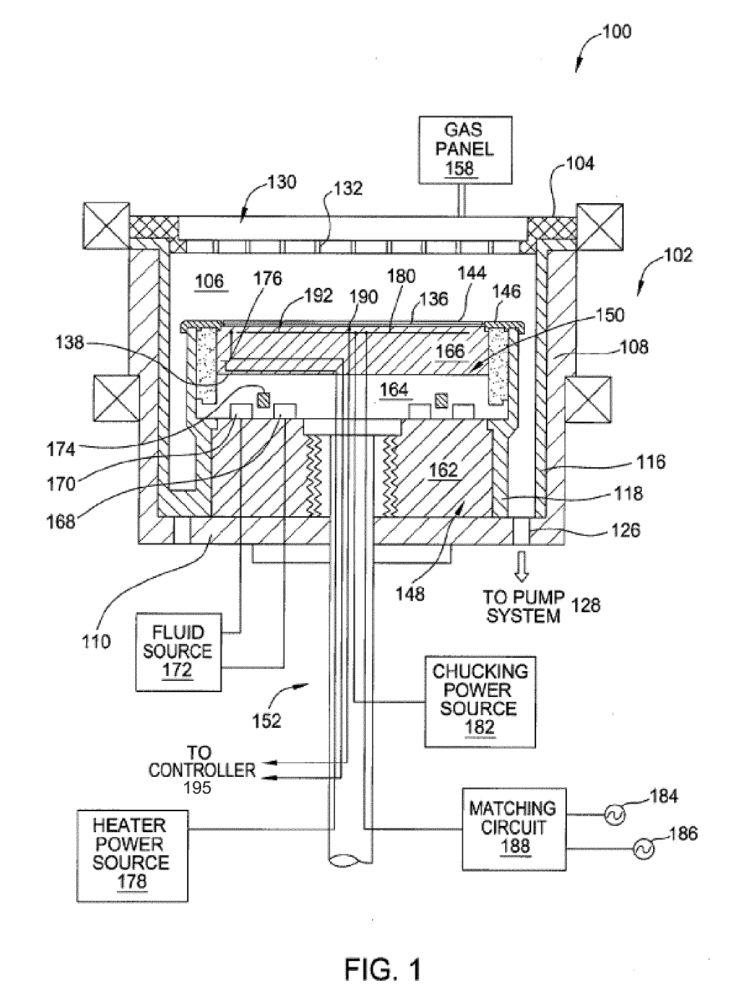

FIG. 1 is a sectional view of one embodiment of a semiconductor processing chamber 100 having a substrate support assembly 148 disposed therein.

The processing chamber 100 includes a chamber body 102 and a lid 104 that enclose an interior volume 106. The chamber body 102 may be fabricated from aluminum, stainless steel or other suitable material. The chamber body 102 generally includes sidewalls 108 and a bottom 110. An outer liner 116 may be disposed adjacent the side walls 108 to protect the chamber body 102. The outer liner 116 may be fabricated and/or coated with a plasma or halogen-containing gas resistant material. In one embodiment, the outer liner 116 is fabricated from aluminum oxide. In another embodiment, the outer liner 116 is fabricated from or coated with yttria, yttrium alloy or an oxide thereof.

An exhaust port 126 may be defined in the chamber body 102, and may couple the interior volume 106 to a pump system 128. The pump system 128 may include one or more pumps and throttle valves utilized to evacuate and regulate the pressure of the interior volume 106 of the processing chamber 100.

The lid 104 may be supported on the sidewall 108 of the chamber body 102. The lid 104 may be opened to allow excess to the interior volume 106 of the processing chamber 100, and may provide a seal for the processing chamber 100 while closed. A gas panel 158 may be coupled to the processing chamber 100 to provide process and/or cleaning gases to the interior volume 106 through a gas distribution assembly 130 that is part of the lid 104. Examples of processing gases may be used to process in the processing chamber including halogen-containing gas, such as C₂F₆, SF₆, SiCl₄, HBr, NF₃, CF₄, CHF₃, CH₂F₃, Cl₂ and SiF₄, among others, and other gases such as O₂, or N₂O. Examples of carrier gases include N₂, He, Ar, and other gases inert to process gases (e.g., non-reactive gases). The gas distribution assembly 130 may have multiple apertures 132 on the downstream surface of the gas distribution assembly 130 to direct the gas flow to the surface of the substrate 144. Additionally, the gas distribution assembly 130 can have a center hole where gases are fed through a ceramic gas nozzle. The gas distribution assembly 130 may be fabricated and/or coated by a ceramic material, such as silicon carbide, bulk Yttrium oxide thereof to provide resistance to halogen-containing chemistries to prevent the gas distribution assembly 130 from corrosion.

The substrate support assembly 148 is disposed in the interior volume 106 of the processing chamber 100 below the gas distribution assembly 130. The substrate support assembly 148 holds the substrate 144 during processing. An inner liner 118 may be coated on the periphery of the substrate support assembly 148. The inner liner 118 may be a halogen-containing gas resist material such as those discussed with reference to the outer liner 116. In one embodiment, the inner liner 118 may be fabricated from the same materials of the outer liner 116.

In one embodiment, the substrate support assembly 148 includes a mounting plate 162 supporting a pedestal 152, and an electrostatic chuck 150. The electrostatic chuck 150 further includes a thermally conductive base 164 and an electrostatic puck 166. The electrostatic puck 166 is a ceramic body that may include internal elements such as heating elements, a chucking electrode, and so forth. An upper surface of the electrostatic puck 166 may be covered by a protective layer 136 in some embodiments. In one embodiment, the protective layer 136 is disposed on the upper surface of the electrostatic puck 166. In another embodiment, the protective layer 136 is disposed on the entire surface of the electrostatic chuck 150 including the outer and side periphery of the thermally conductive base 164 and the electrostatic puck 166.

The protective layer 136 may be a plasma resistant ceramic having a material composition such as Y₂O₃, Y₃Al₅O₁₂ (YAG), Er₂O₃, Er₃Al₅O₁₂ (EAG), a solid solution of Y₂O₃—ZrO₂, or a compound of Y₄Al₂O₉ (YAM) and a solid solution of Y₂₋ₓZrₓO₃ (Y₂O₃—ZrO₂ solid solution). The protective layer 136 may be a sintered bulk ceramic article that was produced from a ceramic powder or a mixture of ceramic powders. Alternatively, the protective layer 136 may be a plasma sprayed or thermally sprayed layer that was produced by plasma spraying (or thermally spraying) a mixture of ceramic powders. Alternatively, the protective layer 136 may be an ion assisted deposition (IAD) coating that was deposited using a bulk composite ceramic target or other bulk ceramic target. Alternatively, the protective layer 136 may be a thin film deposited using atomic layer deposition (ALD).

The mounting plate 162 is coupled to the bottom 110 of the chamber body 102 and includes passages for routing utilities (e.g., fluids, power lines, sensor leads, etc.) to the thermally conductive base 164 and the electrostatic puck 166.

The thermally conductive base 164 and/or electrostatic puck 166 may include one or more optional embedded heating elements 176, embedded thermal isolators 174 and/or conduits 168, 170 to control a lateral temperature profile of the support assembly 148. The conduits 168, 170 may be fluidly coupled to a fluid source 172 that circulates a temperature regulating fluid through the conduits 168, 170. The embedded isolator 174 may be disposed between the conduits 168, 170 in one embodiment. The heater 176 is regulated by a heater power source 178. The conduits 168, 170 and heater 176 may be utilized to control the temperature of the thermally conductive base 164, thereby heating and/or cooling the electrostatic puck 166 and a substrate (e.g., a wafer) being processed. The temperature of the electrostatic puck 166 and the thermally conductive base 164 may be monitored using a plurality of temperature sensors 190, 192, which may be monitored using a controller 195.

The electrostatic puck 166 may further include multiple gas passages such as grooves, mesas and other surface features, that may be formed in an upper surface of the electrostatic puck 166 and/or the protective layer. The gas passages may be fluidly coupled to a source of a thermally conductive gas, such as He via holes drilled in the electrostatic puck 166. In operation, the thermally conductive gas may be provided at controlled pressure into the gas passages to enhance the heat transfer between the electrostatic puck 166 and the substrate 144.

The electrostatic puck 166 includes at least one clamping electrode 180 controlled by a chucking power source 182. The electrode 180 (or other electrode disposed in the electrostatic puck 166 or base 164) may further be coupled to one or more RF power sources 184, 186 through a matching circuit 188 for maintaining a plasma formed from process and/or other gases within the processing chamber 100. The sources 184, 186 are generally capable of producing RF signal having a frequency from about 50 kHz to about 3 GHz and a power of up to about 10,000 Watts.

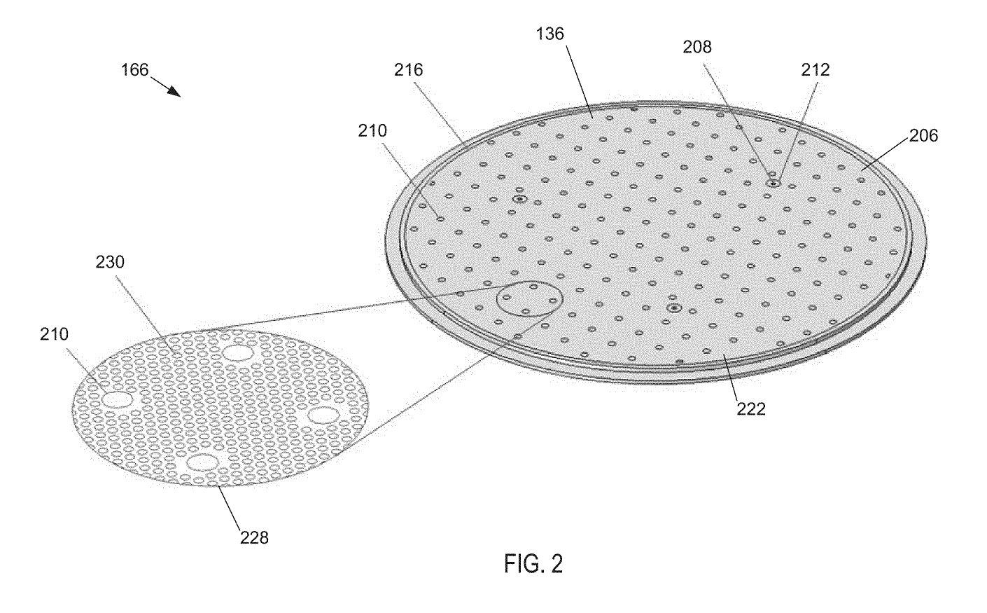

FIG. 2 depicts an exploded view of one embodiment of the electrostatic puck 166 of the substrate support assembly. The electrostatic puck 166 has a disc-like shape having an annular periphery 222 that may substantially match the shape and size of the substrate 144 positioned thereon. In one embodiment, the electrostatic puck 166 may be fabricated by a ceramic material. Suitable examples of the ceramic materials include aluminum oxide (Al₂O₃), aluminum nitride (AlN), titanium oxide (TiO), titanium nitride (TiN), silicon carbide (SiC) and the like.

An upper surface 206 of the electrostatic puck 166 may be coated with the protective layer 136, and may have an outer ring 216, multiple mesas 210, holes for lift pins 208, lift pin sealing rings 212 and recessed features 230 between the mesas.

A zoomed in view 228 of an area of the electrostatic puck 166 between mesas and abutting the outer ring 216 is shown. As shown, the area between the mesas 210 includes multiple recessed features 230 (e.g., blind holes) that improve the TAC of the surface of the electrostatic puck 166.

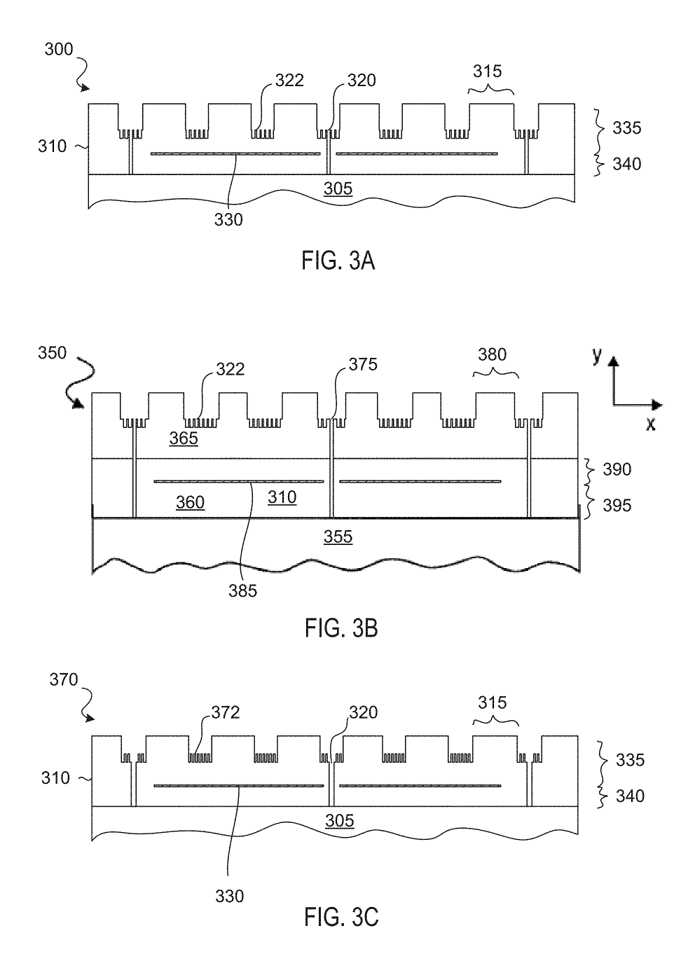

FIG. 3A illustrates a cross sectional side view of one embodiment of an electrostatic chuck 300. The electrostatic chuck 300 has a ceramic body 310 known as an electrostatic puck. The ceramic body 310 includes an electrode 330 embedded therein. In one embodiment, an upper portion 335 of the ceramic body that lies above the electrode 330 has a thickness of greater than 200 micron (e.g., 5 mil in one embodiment). The thickness of the upper portion of the ceramic body 310 may be selected to provide desired dielectric properties such as a specific breakdown voltage. A lower portion 340 of the ceramic body that lies below the electrode 330 may have a thickness of up to about 5 mm. In one embodiment, the entire ceramic body has a thickness of about 5 mm. A lower surface of the ceramic body 310 is bonded to a thermally conductive base 305 (e.g., a metal base). Multiple mesas 315 or dimples are formed on an upper surface of the ceramic body 310. The mesas may be around 10-15 micron tall and about 200 micron in diameter in some embodiments. Additionally, multiple holes 320 are drilled through the ceramic body 310. In one embodiment, the holes 320 have a diameter of about 4-7 mil. In one embodiment, the holes are formed by laser drilling. The holes 320 may deliver a thermally conductive gas, such as helium, to valleys or conduits between the mesas 315. The helium (or other thermally conductive gas) may be provided by a thermally conductive gas source (not shown) that pumps the helium between a substrate and the ceramic body 310 to facilitate heat transfer between the substrate and the ceramic body 310. In one embodiment, a thin protective layer (not shown) may be deposited on the upper surface of the ceramic body 310.

The ceramic body 310 may include a series of recessed features 322 that are formed on the upper surface of the ceramic body 310 that are located in between the mesas 315. The series or pattern of recessed features 322 may be blind holes that are formed to a specified depth without breaking through the bottom surface of the ceramic body 310. The blind holes may have a circular shape, a square shape, a rectangular shape, an oval shape, or any other shape. The shape of the recessed features may be regular or irregular. Additionally, different recessed features may have the same shape or different shapes. The recessed features may also be a series or pattern of trenches. For example, a grid of trenches may be formed, a series of multiple parallel trenches may be formed, etc.

In one embodiment, the recessed features 322 may be formed using an etching process. A masking material may be applied to a portion of the upper surface of the ceramic body 310 that resists an etching chemical or plasma. The ceramic body 310 may be exposed to the etching chemical or plasma to form the recessed features 322, and the masking material may then be removed from the upper surface of the ceramic body 310. In another embodiment, the recessed features 322 may be formed using a bead blasting or salt blasting process where portions of the upper surface of the ceramic body 310 are removed by applying beads or salt at a high pressure to the upper surface of the ceramic body 310. A mask may be placed on the upper surface prior to the bead blasting or salt blasting process. Areas exposed by the mask may form the recessed features 322. The mask may then be removed. Although the recessed features 322 are illustrated as having a planar bottom surface, it should be noted that embodiments may include non-planar bottom surfaces that increase the number of collisions between the molecules of the thermally conductive gas and the surfaces of the recessed features 322. For example, the bottom surface of the recessed features 322 may have a hemispherical shape, a tapered shape, or an angular shape.

FIG. 3B illustrates a cross sectional side view of one embodiment of an electrostatic chuck 350. The electrostatic chuck 350 has a ceramic body 360 known as an electrostatic puck. In one embodiment, the ceramic body 360 includes an electrode 385, an upper portion 390 above the electrode 385 and a lower portion 395 below the electrode. The upper portion 390 may have a thickness of greater than 200 micron (e.g., 5 mil in one embodiment). In a further embodiment, the ceramic body 360 has a thickness of between about 200 micron and 500 micron. A lower surface of the ceramic body 360 is bonded to a thermally conductive base 355 (e.g., a metal base).

An upper surface of the ceramic body 360 is bonded to a protective layer 365. In one embodiment, the protective layer is a plasma sprayed layer. The protective layer 365 may have any of the aforementioned protective layer material compositions. An upper surface of the ceramic body 360 may be roughened prior to plasma spraying the protective coating 365 onto it. The roughening may be performed, for example, by bead blasting the ceramic body 360. Roughening the upper surface of the ceramic body provides anchor points to create a mechanical bond between the plasma sprayed protective layer 365 and the ceramic body 360 for better adhesion.

The protective layer 365 may have an as sprayed thickness of up to about 250 micron or thicker, and may be ground down to a final thickness of approximately 50 microns. Alternatively, the protective layer may be plasma sprayed to a final thickness. The plasma sprayed protective layer 365 may have a porosity of about 2-4%. In one embodiment, a combined thickness of the ceramic body 360 over the electrode and the protective layer 365 is sufficient to provide a total breakdown voltage of >2500V. The ceramic body 360 may be, for example, alumina, which has a breakdown voltage of about 15 Volts/micron (V/μm). The ceramic composite plasma sprayed protective layer 365 may have a breakdown voltage of about 30 V/μm (or about 750 V/mil) in one embodiment. Accordingly, the ceramic body 360 may be about 250 microns thick and the protective layer may be about 50 microns thick to have a breakdown voltage of about 5250 V, for example.

In another embodiment, the protective layer 365 is a bulk sintered ceramic article that is placed on the upper surface of the ceramic body 360. The protective layer 365 may be provided, for example, as a thin ceramic wafer having a thickness of approximately 200 micron. A high temperature treatment may then be performed to promote interdiffusion between the protective layer 365 and the ceramic body 360. The thermal treatment may be a heat treatment at up to about 1400-1500 degrees C. for a duration of up to about 24 hours (e.g., 3-6 hours in one embodiment). This may cause diffusion bonding between the protective layer 365 and the ceramic body 360. The strong adhesion caused by the diffusion bonding allows the protective layer 365 to adhere to the ceramic body securely and prevents the protective layer 365 from cracking, peeling off, or stripping off during plasma processing. After the heat treatment, the protective layer may be ground down to a final thickness. The final thickness may be about 200 micron in one embodiment.

After the protective layer 365 is formed (and ground to a final thickness in some embodiments), mesas 380 and recessed features 322 are formed on an upper surface of the protective layer 365. The mesas 380 and recessed features 322 may be formed, for example, by bead blasting or salt blasting the surface of the protective layer 365. After the protective layer 365 is formed, holes 375 may also be drilled in the protective layer 365 and the underlying ceramic body 360. The embodiments described with reference to FIG. 3B may be used for Columbic electrostatic chucking applications.

FIG. 3C illustrates a cross sectional view of one embodiment of an electrostatic chuck 370. Electrostatic chuck 370 may include similar features to electrostatic chuck 300 illustrated in FIG. 3A. However, the upper surface of the electrostatic chuck 370 may include a series or pattern of protrusions 372 located in between the mesas 315, rather than the series or pattern of recessed features 322 illustrated in FIG. 3A. The protrusions 372 may be formed using, for example, an etching process. A masking material may be applied to a portion of the upper surface of the ceramic body 310 that resists an etching chemical. The ceramic body 310 may be exposed to the etching chemical forming the protrusions 372 and the masking material may be removed from the upper surface of the ceramic body 310. In another embodiment, the protrusions 372 may be formed using a bead blasting or salt blasting process where portions of the upper surface of the ceramic body 310 are removed by applying beads or salt at a high pressure to the upper surface of the ceramic body 310. In another embodiment, the protrusions 372 may be formed by depositing subsequent layers of material. Although the protrusions 372 are illustrated as having a planar top surface, it should be noted that embodiments may include non-planar top surfaces that increase the number of collisions between the molecules of the thermally conductive gas and the surfaces of the protrusions 372. For example, the top surface of the protrusions 372 may have a hemispherical shape or an angular shape. Additionally, the walls of the protrusions may be tapered in some embodiments.

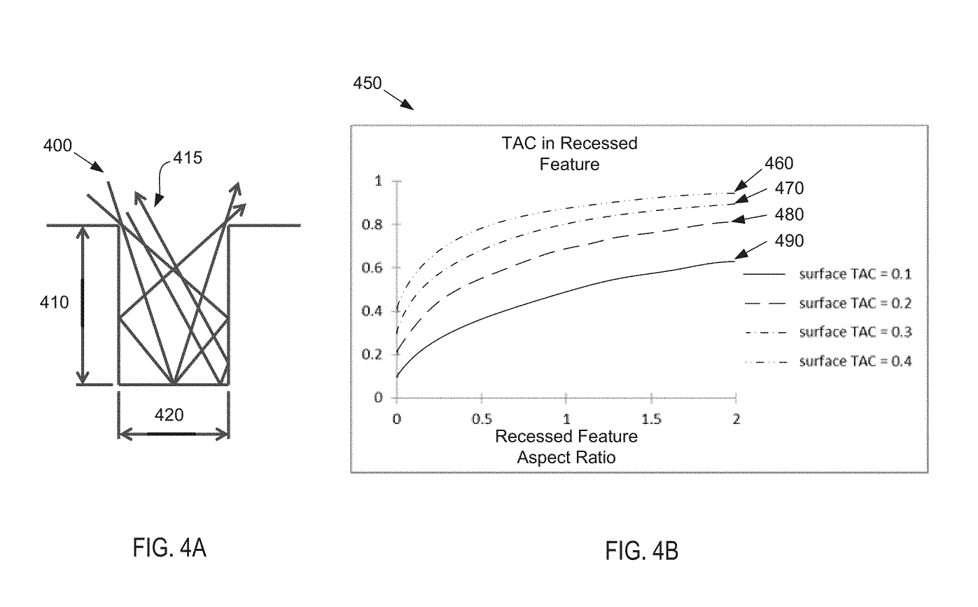

FIG. 4A illustrates a cross sectional side view of a recessed feature 400 in the ceramic body of a substrate support assembly, according to embodiments. The recessed feature 400 may be representative of the recessed features 322 of FIGS. 2, 3A and 3B in embodiments. The recessed feature 400 may include a depth 410 that is the distance from the upper surface of the ceramic body 310 between mesas to the bottom surface of the recessed feature 400. In one embodiment, the recessed feature 400 may have a depth 410 of 1-15 microns, inclusively. Examples of depths include depths in the ranges of 1-3 microns, 3-6 microns, 6-9 microns, 9-12 microns and 12-15 microns. The recessed feature 400 may further include a diameter 420 that is the width or diameter of the recessed feature 400. In one embodiment, the recessed feature 400 may have a width or diameter of 1-20 microns, inclusively. Examples of widths or diameters include widths and diameters in the ranges of 1-5 microns, 5-10 microns, 10-15 microns and 15-20 microns.

The aspect ratio may be the ratio of the depth 410 to the diameter 420 of the recessed features 400. For example, if the recessed feature 400 had a depth 410 of 5 microns and a diameter 420 of 10 microns then the recessed feature 400 may have an aspect ratio of 0.5 (e.g., 5/10). In one embodiment, the recessed feature 400 may have an aspect ratio between 0.1-2 (e.g., 1:10 to 2:1), inclusively. Example aspect ratios are shown in FIG. 4B.

Molecule trajectories 415 are shown. The width 420 and depth 410 of the recessed features as well as the aspect ratio of the recessed features affects the number of collisions between a gas molecule (e.g., a He molecule) and the ceramic body. As shown, the recessed feature may increase the number of collisions between the gas molecule and the ceramic body from 1 collision to 2 or more collisions, depending on the molecular trajectory 415. With each impact the chance of the gas molecule absorbing energy from the ceramic body is increased.

Although embodiments of the present disclosure may describe the recessed feature 400 having a circular geometry, it should be noted that embodiments of the present disclosure may also be utilized using recessed features having non-circular geometries. For example, the recessed features may be rectangular, square, hexagonal, octagonal, or the like. In other embodiments the recessed feature may be holes, ribs, parallel trenches or any structure having side walls to increase the number of collisions between molecules of the thermally conductive gas and the recessed feature and allow the thermally conductive gas to flow freely under the substrate.

FIG. 4B is a graph 450 illustrating the relationship of the aspect ratio of the recessed feature 400 to the effective TAC of the thermally conductive gas in the recessed feature 400. The x-axis of the graph may represent the aspect ratio of the recessed feature 400. The y-axis may represent the effective TAC of the thermally conductive gas and the surface of the ceramic body having the recessed features 400. The graph 450 includes line plots 460, 470, 480, 490 that correspond to surface TAC values 0.4, 0.3, 0.2, 0.1, respectively. The surface TAC may correspond to the TAC value of the thermally conductive gas on the surfaces of the ceramic body having the recessed features 400. Different materials may have different surface TAC values. In one embodiment, the thermally conductive gas may be helium and the surface TAC may be between 0.2-0.9, inclusively. As the aspect ratio of the recessed feature 400 increases, the effective TAC of the gas in the recessed feature 400 may increase asymptotically to 1.

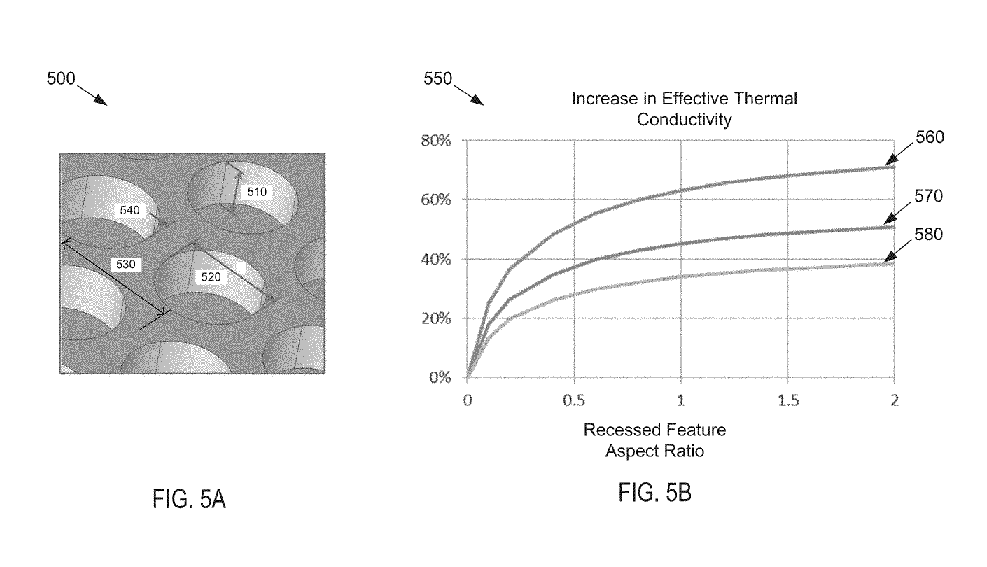

FIG. 5A is an isometric view of the upper surface of the ceramic body 500 including the series of recessed features between mesas. No mesas are shown in FIG. 5A. The recessed features may be representative of the recessed features 322 of FIGS. 2, 3A, 3B and 4A in embodiments. The depth 510 and the diameter 520 may be representative of the depth 410 and diameter 420 of FIG. 4A, respectively. In one embodiment, the depth 510 and/or the diameter 520 may be the same for all recessed features in the ceramic body 500. In another embodiment, the depth 510 and/or diameter 520 may vary. The pitch 530 may be the distance between the center of one recessed feature to the center of an adjacent recessed feature. The diameter 520 and the pitch 530 may be used to determine the distance 540 between the sidewall of one recessed feature to the sidewall of an adjacent recessed feature by subtracting the pitch 530 from the diameter 520. For example, if the diameter 520 of the recessed features is 10 microns and the pitch 530 is 15 microns, then the distance 540 may be 5 microns. In one embodiment, the ratio of the distance 540 between the sidewall of one recessed feature to the sidewall of an adjacent recessed feature to the diameter 520 may be between 0.1 and 1, inclusively. Although the recessed features on the ceramic body 500 are illustrated as being arranged in a staggered pattern, it should be noted that embodiments of the present disclosure may be utilized using an array of aligned rows and columns of recessed features or any other arrangement that increases the number of collisions between the molecules of the thermally conductive gas and the surfaces of the recessed features. Additionally, the surface of the ceramic body may have different pitches between different recessed features.

FIG. 5B is a graph 550 illustrating the relationship of the aspect ratio of the recessed features of the ceramic body 500 to the percent increase of effective thermal conductivity of the thermally conductive gas. The x-axis of the graph may represent the aspect ratio of the recessed features as described in FIG. 4A (e.g., the aspect ratio of the depth to width of the recessed features). The y-axis may represent the percent increase of the effective thermal conductivity of the thermally conductive gas. The percent increase may correspond to an increase in the effective thermal conductivity of the thermally conductive gas in comparison to the effective thermal conductivity of the thermally conductive gas using a ceramic body that does not include recessed features. The graph 550 includes line plots 560, 570, 580 that correspond to ratios of distance 540 to diameter 520. For example, if the distance 540 is 5 microns and the diameter 520 is 10 microns, then the ratio of distance 540 to diameter 520 may be 0.5 (e.g., 5/10). In the present illustration, line plots 560, 570, 580 may correspond to distance 540 to diameter 520 ratios of 0.1, 0.3, 0.5, respectively. As the aspect ratio of the recessed features increases, the percent increase in effective thermal conductivity of the thermally conductive gas may increase asymptotically to an upper limit. The upper limit of the effective thermal conductivity of the thermally conductive gas may correspond to the ratio of distance 540 to diameter 520 of the recessed features, as illustrated by line plots 560, 570, 580. Therefore, when the percent increase in effective thermal conductivity of the thermally conductive gas has reached the upper limit, increasing the aspect ratio of the recessed features no longer increases the effective thermal conductivity of the thermally conductive gas. In one embodiment, the effective thermal conductivity of the thermally conductive gas of an ESC including recessed features may be 40-70% greater than the effective thermal conductivity of the thermally conductive gas of an ESC that does not have the recessed features.

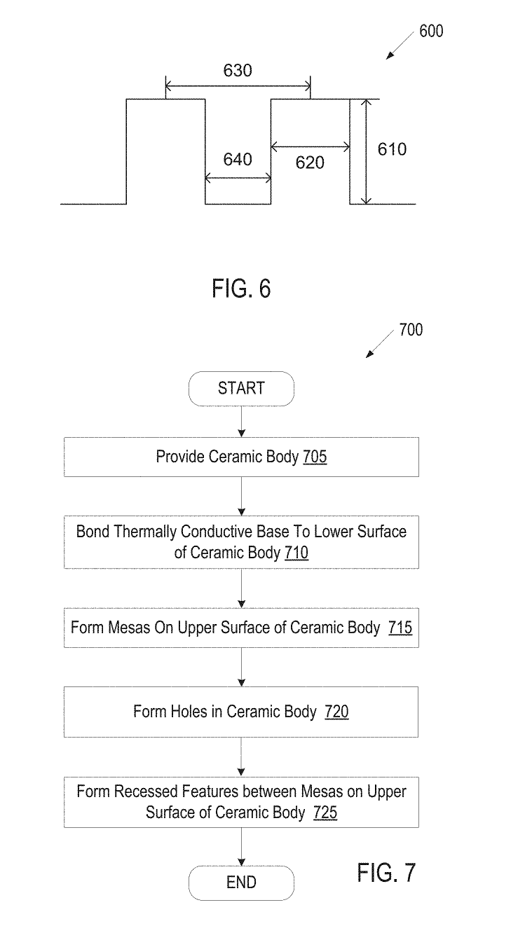

FIG. 6 illustrates a cross sectional view of protrusions 600 in the ceramic body, according to embodiments. The protrusions 600 may be representative of the protrusions 372 of FIG. 3C. The protrusions 600 may include a height 610 that is the distance from the upper surface of the ceramic body 310 between mesas to the top surface of the protrusions 600. In one embodiment, the protrusions 600 may have a height 610 of 1-15 microns, inclusively. In another embodiment, the height 610 may be less than the height of the mesas 315 formed on the ceramic body 310. The protrusions 600 may further include a diameter or width 620. In one embodiment, the protrusions 600 may have a diameter between 1-20 microns, inclusively. In one embodiment, the height 610 and/or the diameter 620 may be the same for all protrusions 600 in the ceramic body 310. In another embodiment, the height 610 and/or diameter 620 may vary. The pitch 630 may be the distance between the center of one protrusion to the center of an adjacent protrusion. The diameter 620 and the pitch 630 may be used to determine the distance 640 between the sidewall of one protrusion to the sidewall of an adjacent protrusion by subtracting the pitch 630 from the diameter 620. For example, if the diameter 620 of the protrusion 600 is 10 microns and the pitch 630 is 15 microns, then the distance 640 may be 5 microns. In one embodiment, the distance 640 may be between 1-20 microns, inclusively. Although embodiments of the present disclosure may describe the protrusions 600 having a circular geometry, it should be noted that embodiments of the present disclosure may also be utilized using protrusions having non-circular geometries. For example, the protrusions may be rectangular, square, hexagonal, octagonal, or the like. In other embodiments the protrusions may be formed to create holes, ribs, parallel trenches or any structure having side walls to increase the number of collisions between molecules of the thermally conductive gas and the recessed feature and allow the thermally conductive gas to flow freely under the substrate.

FIG. 7 illustrates one embodiment of a process 700 for forming recessed features in the ceramic body of a substrate support surface. At block 705 of process 700, a ceramic body is provided. The ceramic body may be a ceramic puck for an electrostatic chuck. The ceramic body may contain heating elements, an electrode, cooling channels, and/or other features. At block 710, a lower surface of the ceramic body is bonded to a thermally conductive base.

At block 715, mesas are formed on an upper surface of the ceramic body. At block 720, holes are formed in the ceramic body (e.g., by laser drilling). At block 725, recessed features are formed between the mesas on the upper surface of the ceramic body (e.g., by etching, bead blasting, etc.). The recessed features may have dimensions as previously described in embodiments. In an alternative embodiment, the ceramic body may be bonded to the base after the mesas are formed, after the holes are formed and/or after the recessed features are formed. In one embodiment, a protective layer may be deposited on the ceramic body.

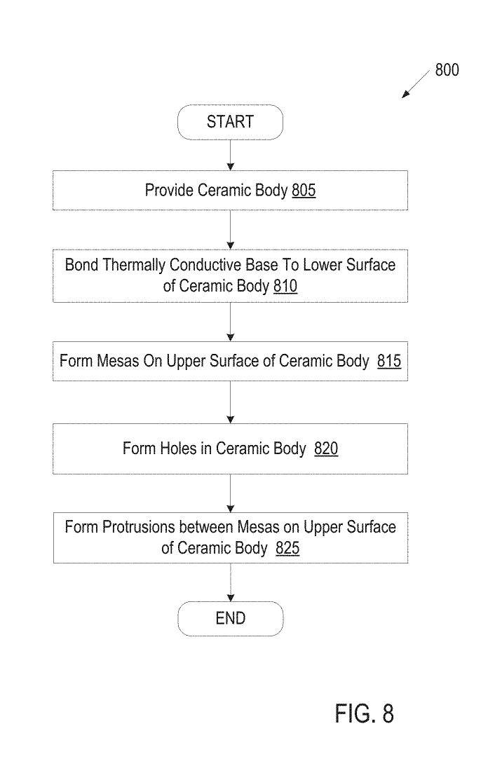

FIG. 8 illustrates another embodiment of a process for forming protrusions on a ceramic body of a substrate support surface. At block 805 of process 800, a ceramic body is provided. At block 810, a lower surface of the ceramic body is bonded to a thermally conductive base.

At block 815, mesas are formed on an upper surface of the ceramic body. At block 820, holes are formed in the ceramic body (e.g., by laser drilling). At block 825, protrusions are formed between the mesas on the upper surface of the ceramic body (e.g., by etching, bead blasting, etc.). The protrusions may have dimensions as previously described in embodiments. In an alternative embodiment, the ceramic body may be bonded to the base after the mesas are formed, after the holes are formed and/or after the protrusions are formed. In one embodiment, a protective layer may be deposited on the ceramic body.

The preceding description sets forth numerous specific details such as examples of specific systems, components, methods, and so forth, in order to provide a good understanding of several embodiments of the present invention. It will be apparent to one skilled in the art, however, that at least some embodiments of the present invention may be practiced without these specific details. In other instances, well-known components or methods are not described in detail or are presented in simple block diagram format in order to avoid unnecessarily obscuring the present invention. Thus, the specific details set forth are merely exemplary. Particular implementations may vary from these exemplary details and still be contemplated to be within the scope of the present invention.

Reference throughout this specification to “one embodiment” or “an embodiment” means that a particular feature, structure, or characteristic described in connection with the embodiment is included in at least one embodiment. Thus, the appearances of the phrase “in one embodiment” or “in an embodiment” in various places throughout this specification are not necessarily all referring to the same embodiment. In addition, the term “or” is intended to mean an inclusive “or” rather than an exclusive “or.” When the term “about” or “approximately” is used herein, this is intended to mean that the nominal value presented is precise within ±10%.

Although the operations of the methods and processes herein are shown and described in a particular order, the order of the operations of each method may be altered so that certain operations may be performed in an inverse order or so that certain operation may be performed, at least in part, concurrently with other operations. In another embodiment, instructions or sub-operations of distinct operations may be in an intermittent and/or alternating manner.

It is to be understood that the above description is intended to be illustrative, and not restrictive. Many other embodiments will be apparent to those of skill in the art upon reading and understanding the above description. The scope of the invention should, therefore, be determined with reference to the appended claims, along with the full scope of equivalents to which such claims are entitled.

What is claimed is:

1. A substrate support assembly comprising:
a ceramic body comprising an upper surface, wherein the upper surface comprises:
a sealing ring at a periphery the ceramic body;
a plurality of mesas; and
a plurality of recessed features, wherein the plurality of recessed features are formed between the plurality of mesas; and
the ceramic body further comprising one or more through holes to receive a thermally conductive gas, wherein molecules of the thermally conductive gas are to collide with walls of the plurality of recessed features to increase an effective thermal accommodation coefficient (TAC) associated with the upper surface and increase an effective thermal conductivity of the thermally conductive gas as a result of the increase in the effective TAC associated with the upper surface.

2. The substrate support assembly of claim 1, wherein the plurality of recessed features comprise a plurality of blind holes.

3. The substrate support assembly of claim 1, wherein bottoms of the plurality of recessed features comprise a hemispherical shape.

4. The substrate support assembly of claim 1, wherein the plurality of recessed features have an aspect ratio of depth to one of width or diameter of between 1:10 and 2:1, inclusive.

5. The substrate support assembly of claim 1, wherein:
the plurality of recessed features have a depth of 1-15 microns, inclusive; and
the plurality of recessed features have a diameter of 1-20 microns, inclusive.

6. The substrate support assembly of claim 1, wherein the thermally conductive gas comprises Helium and the effective TAC of the Helium on the upper surface is about 0.2-0.9, inclusive.

7. The substrate support assembly of claim 1, further comprising a thermally conductive gas source to pump the thermally conductive gas between the upper surface and the substrate, wherein the thermally conductive gas comprises helium.

8. The substrate support assembly of claim 1, wherein the effective thermal conductivity of the thermally conductive gas with the plurality of recessed features is 40-70% greater than the effective thermal conductivity of the thermally conductive gas without the plurality of recessed features.

9. The substrate support assembly of claim 1, wherein an aspect ratio of an average distance between adjacent recessed features of the plurality of recessed features and an average width or diameter of the plurality of recessed features is between 1:10 and 1:1, inclusive.

10. A method comprising:
forming a plurality of mesas on an upper surface of a ceramic body for a substrate support assembly;
forming a sealing ring on the upper surface of the ceramic body;
forming at least one of a) a plurality of recessed features between the plurality of mesas on the upper surface of the ceramic body or b) a plurality of protrusions between the plurality of mesas on the upper surface of the ceramic body; and
forming one or more through holes in the ceramic body, wherein the one or more through holes are to receive a thermally conductive gas, and wherein molecules of the thermally conductive gas are to collide with walls of at least one of the plurality of recessed features or the plurality of protrusions to increase an effective thermal accommodation coefficient (TAC) of the upper surface and increase an effective thermal conductivity of the thermally conductive gas as a result of the increase in the TAC of the upper surface.

11. The method of claim 10, further comprising bonding a thermally conductive base to a lower surface of the ceramic body.

12. The method of claim 10, wherein forming the at least one of (a) the plurality of recessed features or (b) the plurality of protrusions comprises:
disposing a masking material on a first portion of the upper surface of the ceramic body, the masking material to resist etching;
etching a second portion of the upper surface of the ceramic body exposed by the masking material; and
removing the masking material from the first portion of the upper surface of the ceramic body.

13. The method of claim 10, wherein forming the at least one of (a) the plurality of recessed features or (b) the plurality of protrusions comprises:
removing a portion of the upper surface of the ceramic body by applying beads at a high pressure.

14. The method of claim 10, further comprising forming a second plurality of recessed features on an upper surface of the plurality of mesas.

15. A substrate support assembly comprising:
a ceramic body comprising an upper surface, wherein the upper surface comprises:
a sealing ring at a periphery the ceramic body;
a plurality of mesas; and
a plurality of protrusions, wherein the plurality of protrusions are formed between the plurality of mesas; and
the ceramic body further comprising one or more through holes to receive a thermally conductive gas, wherein molecules of the thermally conductive gas are to collide with walls of the plurality of protrusions to increase an effective thermal accommodation coefficient (TAC) associated with the upper surface and increase an effective thermal conductivity of the thermally conductive gas as a result of the increase in the effective TAC associated with the upper surface.

16. The substrate support assembly of claim 15, wherein a top of the plurality of protrusions comprises a hemispherical shape.

17. The substrate support assembly of claim 15, wherein an average distance between a sidewall of a first protrusion of the plurality of protrusions and the sidewall of a second protrusion of the plurality of protrusions is between 1-20 microns, inclusive.

18. The substrate support assembly of claim 15, further comprising a thermally conductive gas source to pump the thermally conductive gas between the upper surface and a supported substrate.

19. The substrate support assembly of claim 15, wherein the thermally conductive gas comprises Helium and the effective TAC of the Helium on the upper surface is about 0.2-0.9, inclusive.

20. The substrate support assembly of claim 15, wherein the protrusions have a height between 1-15 microns, inclusive.
